(19) United States
(12) Patent Application Publication
(10) Pub. No.: US 2011/0147782 A1
(43) Pub. Date: Jun. 23, 2011

(54) OPTICAL DEVICE AND METHOD OF MANUFACTURING THE SAME

(75) Inventors: Hikari SANO, Hyogo (JP); Takahiro NAKANO, Kyoto (JP)

(73) Assignee: PANASONIC CORPORATION, Osaka (JP)

(21) Appl. No.: 13/037,626

(22) Filed: Mar. 1, 2011

Related U.S. Application Data
(63) Continuation of application No. PCT/JP2009/005444, filed on Oct. 19, 2009.

(30) Foreign Application Priority Data
Jan. 30, 2009 (JP) 2009-020572

(51) Int. Cl. H01L 33/58; H01L 21/78

(52) U.S. Cl. 257/98; 438/33; 257/E33.067; 257/E21.599

(57) ABSTRACT

Provided is an optical device which has an increased rate of an area occupied by an effective optical region to an light-transmissive substrate and less noise due to reflection from a peripheral end face of the light-transmissive substrate. The optical device includes a semiconductor substrate in which a light-receiving element is formed and a light-transmissive substrate provided above the semiconductor substrate so as to cover the light-receiving element and fixed to the semiconductor substrate with an adhesive layer. The light-transmissive substrate has, in a peripheral end face, a curved surface which slopes so as to flare from an upper surface toward a lower surface.

### CROSS REFERENCE TO RELATED APPLICATION(S)

This is a continuation application of PCT application No. PCT/JP2009/005444 filed on Oct. 19, 2009, designating the United States of America.

### BACKGROUND OF THE INVENTION

(1) Field of the Invention

The present invention relates to semiconductor devices for use in digital cameras or mobile phones, for example, optical devices in which light-receiving elements typified by imaging devices and photo ICs or light-emitting devices typified by LEDs and laser devices are formed, electronic apparatuses in which such semiconductor devices are used, and methods of manufacturing such optical devices.

(2) Description of the Related Art

In recent years, for semiconductor devices for use in various electronic apparatuses, there is an increasing demand for miniaturization, reduction in thickness and weight, and packaging at higher density. In addition, along with higher integration of semiconductor devices due to advancement in microfabrication techniques, packaging techniques have been presented which allow direct mounting of a semiconductor device in a chip-size package or a bare chip on a substrate, what is called chip mounting techniques.

For example, miniaturization and chip mounting of optical devices have been achieved by a technique in which a light-receiving or -emitting surface of the front surface of a semiconductor substrate in which an optical element is formed is sealed with a light-transmissive substrate equivalent in area to the semiconductor substrate, and external electrodes are provided on the back surface side of the semiconductor substrate.

As an example of conventional optical devices, the following briefly describes a solid-state imaging device including through electrodes as shown in FIG. 10 (for example, see WO2005/022631 (Patent Reference 1)). The conventional optical device shown in FIG. 10 includes a semiconductor substrate 101, a plurality of light-receiving elements 102 provided in the front surface of the semiconductor substrate 101, and microlenses 103 provided above the front surface of the semiconductor substrate 101. The semiconductor substrate 101 is bonded to a light-transmissive substrate 104 with an adhesive layer 105 provided above a peripheral region of the semiconductor substrate 101. The light-transmissive substrate 104 is equivalent in area to the semiconductor substrate 101. The semiconductor substrate 101 has through holes 107 which penetrate through the semiconductor substrate 101 from the front surface to the back surface, and a through electrode 106 is provided in each of the through hole 107. The through electrode 106 is composed of a conductive film 109 and a conductive body 110. The conductive body 110 has an opening on a part thereof, and the part serves as an external terminal 110a. An insulating film 108 is provided on the back surface of the semiconductor substrate 101. The lower surface of the insulating film 108 and the lower surface of the conductive body 110 are covered with an overcoat 115 except where the external terminal 110a is present. An external electrode 112 is provided in contact with the external terminal 110a. On the side of the front surface of the semiconductor substrate 101, electrodes 111 and an insulating film 113 are provided.

In the case of such a conventional optical device including a light-transmissive substrate on a light-receiving or -emitting surface of a semiconductor substrate, there may be noise, such as ghosting or flare, due to reflection from a peripheral end face of the light-transmissive substrate.

In a conventional solid-state imaging device, a peripheral end face of a light-transmissive substrate is slanted so that oblique incident light reflected from the peripheral end face of the light-transmissive substrate is prevented from reaching a light-receiving surface of a semiconductor substrate, so that occurrence of ghosting or flare is reduced (for example, see Japanese Unexamined Patent Application Publication Number 1-248673 (Patent Reference 2)). However, in the solid-state imaging device, the area size of the upper surface of the light-transmissive substrate, which is a surface parallel to the light-receiving surface, is reduced by slanting the peripheral end face. The smaller the angle between the slanted peripheral end face of the light-transmissive substrate and the light-receiving surface is, the more effective for reduction of noise due to reflection the shape of the peripheral end face is. However, the smaller the angle is, the smaller the effective region of the light-transmissive substrate is. Therefore, making the angle smaller has an adverse effect on increase in the rate of the effective region to the light-transmissive substrate.

On the other hand, further higher integration of a semiconductor device due to progress in fine-processing techniques and advances in chip mounting techniques have been increasing the rate of an area occupied by an effective optical region to a semiconductor substrate. Along with this, the demand for a light-transmissive substrate with a higher rate of an effective region has been increasing.

For example, when a large semiconductor substrate is sealed with a light-transmissive substrate which is large as well, and a plurality of unit structures each including an optical element are formed in the large semiconductor substrate with predetermined intervals, the large semiconductor substrate is separated into the unit structures, and singulated optical devices are thus obtained. In this method of manufacturing chips to be mounted, the area size of each singulated light-transmissive substrate is limited to an area size equivalent to that of the singulated semiconductor substrate. Therefore, when the effective optical region of the light-transmissive substrate is limited, the region of an optical element in a semiconductor substrate is also limited. Such limitation of the effective optical region of the light-transmissive substrate may limit miniaturization of semiconductor substrates or increase in the rate of an area occupied by an effective optical region to a semiconductor substrate.

In recent years, as can be seen in a solid-state imaging device including the above-mentioned through electrode or a back-side illumination imaging device (see Japanese Unexamined Patent Application Publication Number 2003-31785 (Patent Reference 3)), the rate of an area occupied by an effective optical region to a semiconductor substrate has been expected to be increased by providing an external terminal on the surface opposite to the light-receiving or -emitting region of the semiconductor substrate. Furthermore, there has been an increasing demand for chip mounting of optical devices including a light-transmissive substrate equivalent in area to a semiconductor substrate for the purpose of further miniaturization of optical devices, which increases demand for a higher rate of an effective region to a light-transmissive substrate.

The present invention, conceived to address the problems, has an object of providing an optical device which has an increased rate of an area occupied by an effective optical region to an light-transmissive substrate and less noise due to reflection from a peripheral side face of the light-transmissive substrate. In other words, the object is to provide an optical device which is small in area and has excellent optical properties with a large effective optical region.

### SUMMARY OF THE INVENTION

In order to achieve the above object, the optical device according to an aspect of the present invention includes: a semiconductor substrate in which an optical element is formed; and a light-transmissive substrate provided above the semiconductor substrate so as to cover the optical element, wherein the light-transmissive substrate has, in a peripheral end face, a curved surface which slopes so as to flare from an upper surface of the light-transmissive substrate toward a lower surface of the light-transmissive substrate.

In this configuration, the closer to the peripheral end face, the less thick the light-transmissive substrate is in the peripheral region. With this, reflection from the peripheral end face of the light-transmissive substrate into the optical element is reduced, and thus generation of noise due to reflection from the peripheral end face of the light-transmissive substrate is prevented. In addition, the effective optical region in the light-transmissive substrate having the curved peripheral end face is larger than in the case where a light-transmissive substrate of the same size has a conventional slanted peripheral end face, so that the effective optical region occupies a high rate of an area of the light-transmissive substrate.

As described above, the optical device according to the present invention prevents generation of noise due to reflection from the peripheral end face of the light-transmissive substrate. In addition, the effective optical region occupies a high rate of an area of even a small light-transmissive substrate in comparison with a light-transmissive substrate having a slanted peripheral end. The present invention is therefore applicable particularly to optical devices mounted with a chip including a light-transmissive substrate equivalent in area to a semiconductor substrate in the chip, such as optical devices typified by solid-state imaging devices having through electrodes and back-side illumination imaging devices and to electronic apparatuses in which such optical devices are used.

In addition, in the method of manufacturing the optical device according to the present invention, damage to elements in a step of dicing (chip separation step) is reduced, and the optical device is provided with a configuration which allows mounting of miniaturized chips at high productivity. The present invention thus provides an optical device which is small in area and highly reliable, and has excellent optical properties.

The present invention, which enables miniaturization and of various optical sensors of devices such as medical devices, digital optical devices such as digital still cameras, cameras for mobile phones, and camcorders, and enhances functionality of these devices, has a high practical value when applied to a variety of optical devices and apparatuses.

### FURTHER INFORMATION ABOUT TECHNICAL BACKGROUND TO THIS APPLICATION

The disclosure of Japanese Patent Application No. 2009-020572 filed on Jan. 30, 2009 including specification, drawings and claims is incorporated herein by reference in its entirety.

The disclosure of PCT application No. PCT/JP2009/005444 filed on Oct. 19, 2009, including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 illustrates a perspective view of a solid-state imaging device according to an embodiment of the present invention;

FIG. 2A illustrates a sectional view of the solid-state imaging device of the embodiment;

FIG. 2B illustrates a sectional view of the solid-state imaging device;

FIG. 3A illustrates a schematic view of the solid-state imaging device according to the embodiment;

FIG. 3B illustrates a schematic view of the solid-state imaging device according to the embodiment;

FIG. 4 illustrates a sectional view of an optical module including the solid-state imaging device according to the embodiment;

FIG. 5A illustrates a sectional view for explaining a method of manufacturing the solid-state imaging device according to the embodiment;

FIG. 5B illustrates a sectional view for explaining the method of manufacturing the solid-state imaging device according to the embodiment;

FIG. 5C illustrates a sectional view for explaining the method of manufacturing the solid-state imaging device according to the embodiment;

FIG. 5D illustrates a sectional view for explaining the method of manufacturing the solid-state imaging device according to the embodiment;

FIG. 5E illustrates a sectional view for explaining the method of manufacturing the solid-state imaging device according to the embodiment;

FIG. 5F illustrates a sectional view for explaining the method of manufacturing the solid-state imaging device according to the embodiment;

FIG. 5G illustrates a sectional view for explaining the method of manufacturing the solid-state imaging device according to the embodiment;

FIG. 5H illustrates a sectional view for explaining the method of manufacturing the solid-state imaging device according to the embodiment;

FIG. 6A illustrates a sectional view for explaining the method of manufacturing the solid-state imaging device according to the embodiment;

FIG. 6B illustrates a sectional view for explaining the method of manufacturing the solid-state imaging device according to the embodiment;

FIG. 6C illustrates a sectional view for explaining the method of manufacturing the solid-state imaging device according to the embodiment;

FIG. 7 illustrates a perspective view for explaining the method of manufacturing the solid-state imaging device according to the embodiment;

FIG. 8A illustrates a sectional view for explaining a variation of the method of manufacturing the solid-state imaging device according to the embodiment;

FIG. 8B illustrates a sectional view for explaining a variation of the method of manufacturing the solid-state imaging device according to the embodiment;

FIG. 9A illustrates a schematic view of a variation of the solid-state imaging device according to the embodiment;

FIG. 9B illustrates a schematic view of a variation of the solid-state imaging device according to the embodiment; and

FIG. 10 illustrates a sectional view of a conventional solid-state imaging device.

### DESCRIPTION OF THE PREFERRED EMBODIMENT(S)

The following describes a solid-state imaging device as an example of an optical device according to the present invention and a method of manufacturing the solid-state imaging device with reference to the drawings.

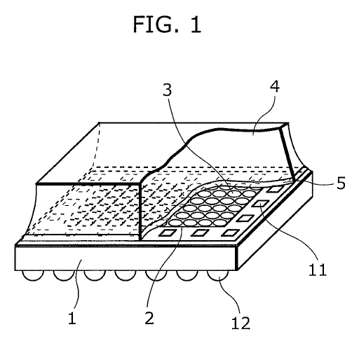

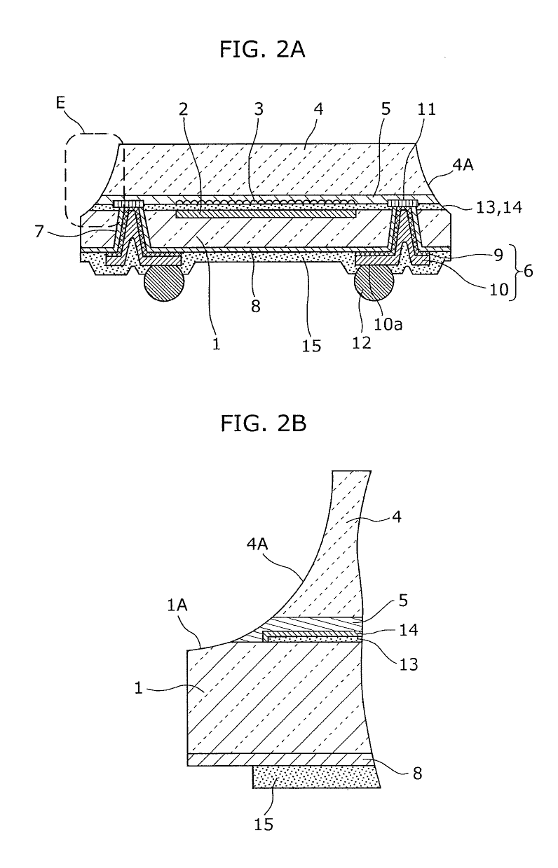

FIG. 1 illustrates a perspective view (a perspective cutaway view) of a solid-state imaging device according to an embodiment. FIG. 2A illustrates a sectional view of the solid-state imaging device. FIG. 2B is a sectional view (an enlarged sectional view of a peripheral region E indicated in FIG. 2A) of the solid-state imaging device.

As shown in FIG. 1, FIG. 2A, and FIG. 2B, the solid-state imaging device according to the embodiment includes a semiconductor substrate 1, microlenses 3, a light-transmissive substrate 4, an adhesive layer 5, through electrodes 6, an insulating film 8, electrodes 11, external electrodes 12, an insulating film 13, a passivation film 14, and an overcoat 15.

In a front surface of the semiconductor substrate 1 (an upper surface in FIG. 1, FIG. 2A, and FIG. 2B, hereinafter referred to as an upper surface), a plurality of light-receiving elements (an example of optical elements) 2 is formed by semiconductor processes. A surface of a peripheral region of the semiconductor substrate 1 is provided with peripheral circuitry (not shown) for driving and controlling the light-receiving elements 2.

The light-transmissive substrate 4, which may be a glass substrate, is provided above the semiconductor substrate 1 so as to cover the light-receiving elements 2. A back surface of the light-transmissive substrate 4 (a lower surface in FIG. 1, FIG. 2A, and FIG. 2B, hereinafter referred to as a lower surface) is adhesively fixed to the upper surface of the semiconductor substrate 1 with the adhesive layer 5. The lower surface of the light-transmissive substrate 4 is equivalent in area to the upper surface of the semiconductor substrate 1. The light-transmissive substrate 4 provided so as to cover the light-receiving element 2 protects the light-receiving element 2, prevents dust from attaching to the light-receiving unit 2 and being captured in a picture, and enables the semiconductor substrate 1 to withstand processing and handling.

As shown in FIG. 2A, in the solid-state imaging device according to the embodiment, the electrodes 11 are formed above the surface of the semiconductor substrate 1 in the peripheral region, and the upper surface of the semiconductor substrate 1 is covered with the insulating film 13. In the insulating film 13, conductive bodies (not shown) are formed so as to electrically connect elements and the electrodes 11.

On the upper surface side of the semiconductor substrate 1, the passivation film 14 is formed so as to cover the surface of the insulating film 13 as shown in FIG. 2B. The passivation film 14 may have an opening at least above part of the surface of each of the electrodes 11. The part of the surface in the opening is used as, for example, a testing terminal in a semiconductor process.

The insulating film 13 and the passivation film 14 preferably have an opening in a region close to the peripheral side face, that is, a region above where a large semiconductor substrate is to be separated for singulation of the semiconductor substrate 1 in a manufacturing process described below (scribe region) so that occurrence of chipping in the step of dicing is reduced.

On the surface of the passivation film 14 between the semiconductor substrate 1 and the adhesive layer 5, each of the microlenses 3 is disposed in a position corresponding to each of the light-receiving element 2. Color filters may be further provided between the microlenses 3 and the passivation film 14.

When the adhesive layer 5 is provided so as to cover the surface of the light-receiving element 2 as shown in FIG. 2A, the adhesive layer 5 is preferably made of a material having a refractive index close to those of the microlenses 3 and the light-transmissive substrate 4. In this case, angles of refraction of incident light at an interface between the adhesive layer 5 and the microlenses 3 and at an interface between the adhesive layer 5 and the light-transmissive substrate 4 is made smaller so that a constraint on thickness of the adhesive layer 5 is relaxed, and thus enhancing performance in light collection to the light-receiving element 2.

In the peripheral region of the semiconductor substrate 1, through holes 7 are provided to penetrate through the semiconductor substrate 1 from the upper surface to a back surface (a lower surface in FIG. 1, FIG. 2A, and FIG. 2B, hereinafter referred to as a lower surface). The through holes 7 have a cylindrical shape. As shown in FIG. 2A, in each of the through holes 7, the insulating film 8 is provided in contact with an inside wall of the through hole 7 so as to have a cylindrical shape to cover the inner wall of the through hole 7. The through electrodes 6 are provided in contact with the inner walls of the cylinders of the insulating film 8.

The through electrodes 6 each include a conductive film 9 having a cylindrical shape in the through hole 7 and a conductive body 10 having a columnar shape and a thickness larger than that of the conductive film 9 and provided in contact with the conductive film 9 in the through hole 7. The conductive film 9 in each of the through electrodes 6 is electrically connected to a corresponding one of the electrode 11.

The insulating film 8 covers all of the lower surface of the semiconductor substrate 1 except the through electrodes 6. On the insulating film 8 on the lower surface of the semiconductor substrate 1, wiring is provided integrally with the conductive films 9 and the conductive bodies 10 of the through electrodes 6, and each of the conductive bodies 10 is exposed in a region to serve as an external terminal 10a. All of the surface of the insulating film 8 and the surface of the conductive bodies 10 are covered with the overcoat 15 except the regions serving as the external terminals 10a and in the region close to the peripheral end face of the semiconductor substrate 1.

On the lower surface side of the semiconductor substrate 1, the external electrodes 12 are provided in contact with the external terminals 10a. The external electrodes 12 are electrically connected to the peripheral circuitry on the upper surface side of the semiconductor substrate 1 through the respective through electrodes 6 and electrodes 11. The light-receiving elements 2 are electrically connected to the peripheral circuitry. Providing the external terminals 10a on the back surface, which is the surface opposite to the light-receiving or -emitting surface of the semiconductor substrate 1, allows reduction in the width of the peripheral portion of the semiconductor substrate 1, and thus miniaturization of the semiconductor substrate 1 and increase in the rate of an area occupied by the effective optical region are expected.

Basic configuration of the solid-state imaging device according to the embodiment is understandably described above. The following describes features of the solid-state imaging device according to the embodiment.

As shown in FIG. 1, FIG. 2A, and FIG. 2B, the light-transmissive substrate 4 of the solid-state imaging device according to the embodiment has, in the peripheral end face, a curved surface 4A which slopes so as to flare gradually from the upper surface toward the lower surface, so that the light-transmissive substrate 4 becomes thinner in the peripheral region toward the peripheral end face. The curved surface 4A reduces incidence of reflection from the peripheral end face of the light-transmissive substrate 4 on the light-receiving surface, so that generation of noise is prevented. In addition, an effective optical region of the light-transmissive substrate 4 having such a curved peripheral end face (peripheral side face) is larger than in the case where the light-transmissive substrate 4 of the same size has a slanted peripheral end face as in the conventional technique, thus allowing effective miniaturization of the light-transmissive substrate 4.

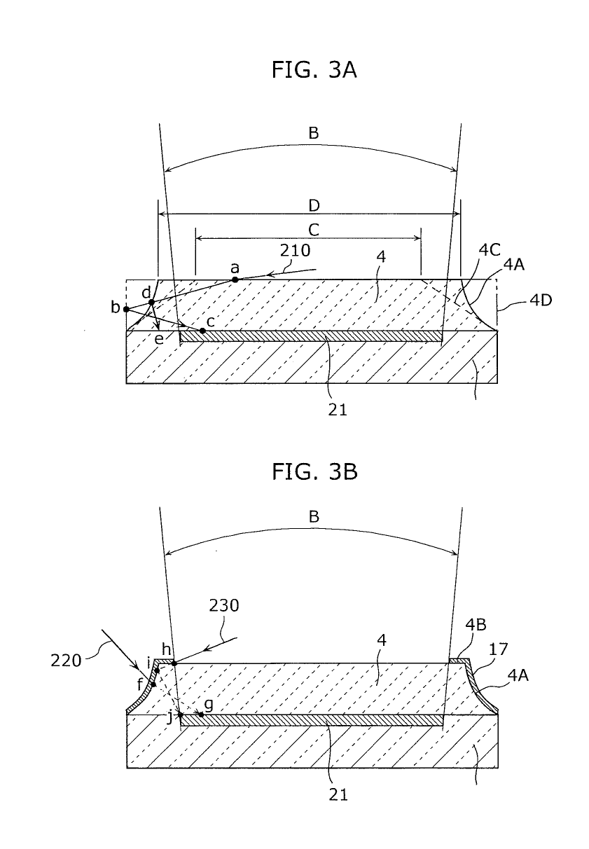

The following describes advantageous effects of the solid-state imaging device according to the embodiment in detail with reference to FIG. 3A and FIG. 3B. FIG. 3A and FIG. 3B illustrate schematic views of a cross-section structure of the solid-state imaging device according to the embodiment. Since FIG. 3A and FIG. 3B are provided for the purpose of illustrating effects of the solid-state imaging device, the drawings are simplified so that only the light-transmissive substrate 4, the semiconductor substrate 1, and the light-receiving element 2 are schematically shown and other components are not shown there.

As shown in FIG. 3A, the front surface of the light-transmissive substrate 4 (an upper surface in FIG. 3A and FIG. 3B, hereinafter referred to as an upper surface) intersects with a tangent plane 4C to the curved surface 4A at where the curved surface 4A is in contact with the lower surface of the light-transmissive substrate 4, that is, a tangent plane 4C at a rising of the curved surface 4A at the outmost edge. The line of intersection between the upper surface of the light-transmissive substrate 4 and the curved surface 4A is located outward of the line of intersection between the upper surface of the light-transmissive substrate 4 and the tangent plane 4C to the curved surface 4A. Therefore, an upper surface region D of the light-transmissive substrate 4 provided with the curved surface 4A is larger in area than an upper surface region C of a light-transmissive substrate 4 provided with a slanted end face. This allows the light-transmissive substrate 4 to have a large effective optical region B corresponding to the light-receiving element 2. For the light-receiving elements 2 of the same size, the light-transmissive substrate 4 having the curved surface 4A as the peripheral end face may be made smaller than a light-transmissive substrate having a slanted peripheral end face.

In addition, as shown in FIG. 3A, in the case where a peripheral end face of the light-transmissive substrate 4 is a perpendicular face 4D which is perpendicular to the lower surface, oblique incident light 210 entering from a point a on the upper surface of the light-transmissive substrate 4 is reflected off a point b on the peripheral side face to be incident on a point c on the light-receiving element 2. In contrast, in the case where the peripheral end face of the light-transmissive substrate 4 is the curved surface 4A, the oblique incident light 210 is reflected off a point d on the curved surface 4A to reach a point e outside the effective region of the semiconductor substrate 1. The oblique incident light 210 reflected off the peripheral end face of the light-transmissive substrate 4 thus has no effect on optical properties of the optical device. In this manner, in the case where the light-transmissive substrate 4 has the curved surface 4A, the angle of reflection decreases depending on an oblique angle of a tangent plane to the curved surface 4A with respect to a normal to the lower surface of the light-transmissive substrate 4, and the oblique incident light reflected off the peripheral end face of the light-transmissive substrate 4 is directed further downward. Noise due to oblique incident light reflected off the peripheral end face of the light-transmissive substrate 4 is thus reduced.

It is preferable that as shown in FIG. 3B, the light-transmissive substrate 4 have a light shield structure including a light shield film 17 on the region other than the effective optical region, that is, on the curved surface 4A and the upper surface 4B which is in the peripheral region of the light-transmissive substrate 4. By blocking light incident on the curved surface 4A outside the effective optical region, oblique incident light 220 is prevented from entering from a point f on the curved surface 4A to be incident on a point g on the light-receiving element 2. In addition, by shielding the upper surface 4B in the peripheral region of the light-transmissive substrate 4 from light, oblique incident light 230 is prevented from entering from a point h on the upper surface 4B out of the effective region and in the peripheral region of the light-transmissive substrate 4 and reflected off a point i on the curved surface 4A to be incident on a point j on the light-receiving element 2. Noise due to incident light from the region outside the effective region is thus prevented by providing the light-shielding structure to the light-transmissive substrate 4. In addition, in the case where oblique angles of tangent planes to the curved surface 4A with respect to a normal to the lower surface of the light-transmissive substrate 4 is smaller for tangent points closer to the upper surface of the light-transmissive substrate 4 than for tangent points closer to the lower surface as shown in FIG. 3A and FIG. 3B, noise due to oblique incident light reflected off an upper part of the curved surface 4A may have a great impact. However, the light shield film 17 provided in contact with the upper surface 4B in the peripheral region of the light-transmissive substrate 4 blocks the oblique incident light 230, which is to be reflected off an upper part of the curved surface 4A, at the upper surface of the light-transmissive substrate 4. Therefore, effect of reducing noise due to reflected oblique incident light is not diminished even in the case where the peripheral end face of the light-transmissive substrate 4 is the curved surface 4A having tangent planes thereto at tangent points on an upper-surface side forms a small oblique angle with a normal to the lower surface of the light-transmissive substrate 4.

In addition, it is preferable that, as shown in FIG. 2B, the upper surface of the peripheral region of the semiconductor substrate 1 be chamfered in a manner such that the semiconductor substrate 1 has, in the peripheral end face thereof, a curved surface 1A which forms a continuous curve with the curved surface 4A of the light-transmissive substrate 4. This is effective in preventing chipping in a process of dicing or handling after the dicing, which is described later.

In addition, it is preferable that the curved surface 4A of the light-transmissive substrate 4 be rough because such a rough surface diminishes light reflected off or transmitted through the curved surface 4A, thus further reducing noise due to reflection of oblique incident light.

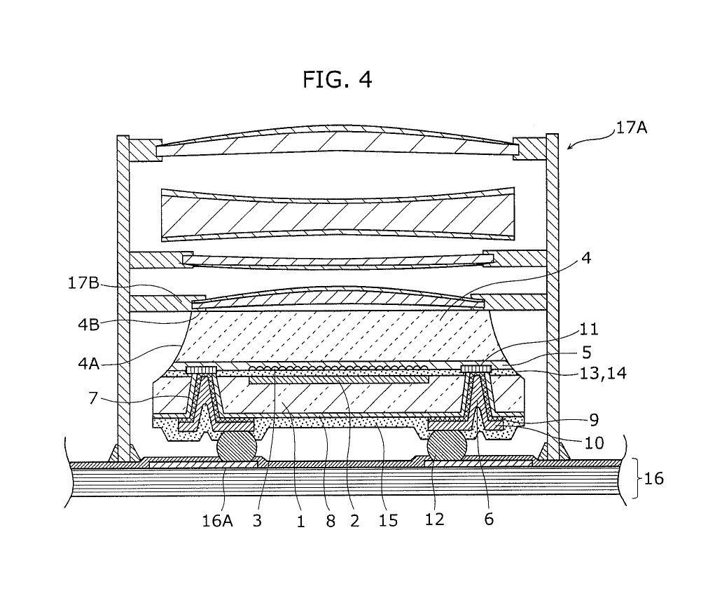

The following describes an example of an optical module including the solid-state imaging device according to the embodiment with reference to FIG. 4. FIG. 4 illustrates a sectional view of a configuration of the optical module.

The optical module includes the solid-state imaging device according to the embodiment, a lens tube 17A, and a circuit board 16 which is provided on the lower surface side of the semiconductor substrate 1 of the solid-state imaging device. The external electrodes 12 and mounting terminals 16A provided on the circuit board 16 are electrically connected. The lens tube 17A is disposed on the upper surface side of the light-transmissive substrate 4.

Here, it is preferable that the curved surface 4A of the light-transmissive substrate 4 and the upper surface 4B of the peripheral region be shielded from light by a support structure 17B of the lens tube 17A so that the same effect is achieved as in the case where the light shield film 17 is provided on the solid-state imaging device. This eliminates the need for providing a light shield structure, that is, the light shield film 17, in the solid-state imaging device, and thus providing effective light shielding.

In addition, it is preferable that the lens tube 17A be disposed with reference to a contact surface of the upper surface 4B in the peripheral region of the light-transmissive substrate with the support structure 17B, that is, the upper surface 4B so that accuracy in distortion correction by adjusting the lens tube 17A with respect to the light-receiving element 2 is increased, thus eliminating the need for a adjustment mechanism for distortion correction when the lens tube 17A is installed.

As described above, in the solid-state imaging device according to the embodiment, generation of noise due to reflection off the peripheral side face of the light-transmissive substrate 4 is reduced, and the rate of an area occupied by an effective optical region to the light-transmissive substrate 4 is increased. The solid-state imaging device according to the embodiment is therefore appropriately applied to small optical devices including a light-transmissive substrate 4 equivalent in area to the semiconductor substrate 1 or smaller. In addition, the solid-state imaging device according to the embodiment is effective for optical devices in which the rate of the light-receiving element 2 to the semiconductor substrate 1 is high and the peripheral region is narrow. For example, the solid-state imaging device according to the embodiment is appropriately applied to an optical device including the through electrodes 6 as shown in the solid-state imaging device according to the embodiment, which has the external electrodes 12 on the back surface which is opposite to the light-receiving or -emitting surface of the semiconductor substrate 1, and to a back-side illumination optical device. In particular, when optical devices are manufactured using a chip-size packaging method in which a plurality of optical devices is formed on a large light-transmissive substrate together and the large light-transmissive substrate is diced into the optical devices, the size of the light-transmissive substrate 4 is limited to the size of the semiconductor substrate 1. The solid-state imaging device according to the embodiment is therefore effective for miniaturization of optical devices and increase of the rate of an area occupied by an effective optical region of an optical device manufactured using the chip-size packaging.

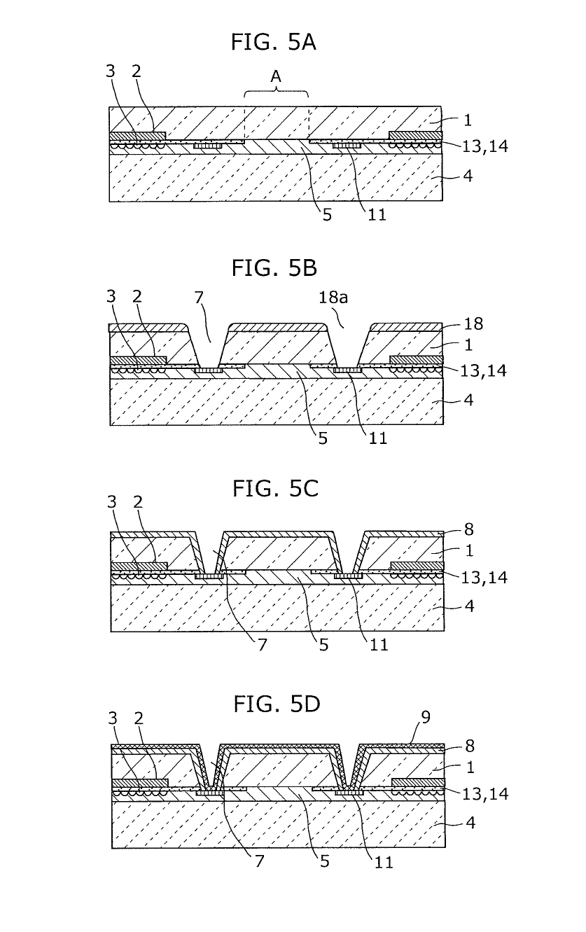

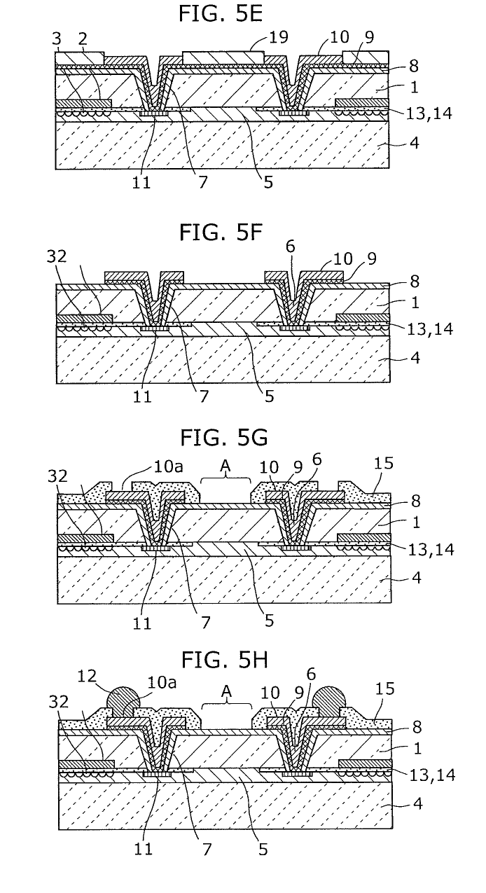

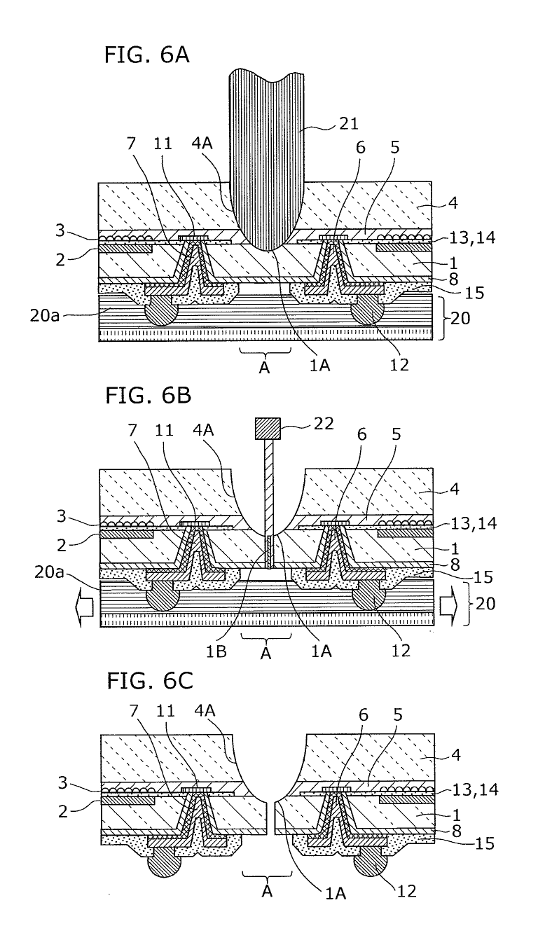

The following describes an exemplary method of manufacturing the solid-state imaging device according to the embodiment shown in FIG. 1, FIG. 2A, and FIG. 2B, with reference to FIG. 5A to FIG. 6C. In the method of manufacturing the solid-state imaging device according to the embodiment, the semiconductor substrate 1 is provided by separating, into singulated chips, a large semiconductor substrate (a semiconductor wafer) 1 having a plurality of the light-receiving elements 2 with regular intervals in the front surface thereof. The light-transmissive substrate 4 to be fixed to the surface of the semiconductor substrate 1 with the adhesive layer 5 is also provided by separating a large one. In order to avoid explanatory confusion, the semiconductor wafer is hereinafter referred to as the semiconductor substrate 1, and the large light-transmissive substrate 4 is hereinafter referred to as the light-transmissive substrate 4.

FIG. 5A to FIG. 6C illustrate sectional views schematically showing a structure between centers of a pair of unit structures of the optical devices sandwiching a portion to be cut in to separate the large semiconductor substrate 1 into singulated chips, that is, a scribe region A.

First, the following describes steps through which optical devices are formed on the large semiconductor substrate 1 with reference to FIG. 5A to FIG. 5H. It is to be noted that, in the steps shown in FIG. 5A to FIG. 5H, the fabrication process is advanced with the semiconductor substrate 1 disposed upside down from that shown in FIG. 1, FIG. 2A, and FIG. 2B. The vertical directions of the semiconductor substrate 1 shown in FIG. 5A to FIG. 5H are described according to the drawing, so that the vertical directions indicate directions opposite to those indicated in FIG. 1, FIG. 2A, and FIG. 2B.

First, as shown in FIG. 5A, above the semiconductor substrate 1 on which light-receiving elements 2, microlenses 3, an electrode 11, an insulating film 13, and a passivation film 14 are formed, a light-transmissive substrate 4 is disposed so as to cover the light-receiving element 2. The light-transmissive substrate 4 is bonded to the semiconductor substrate 1 with an adhesive layer 5, so that the light-transmissive substrate 4 and the semiconductor substrate 1 are integrated. Next, the upper surface (the lower surface in FIG. 2A and FIG. 2B) of the semiconductor substrate 1 is polished to thin the semiconductor substrate 1 to a predetermined thickness, using the light-transmissive substrate 4 as a support.

Next, as shown in FIG. 5B, a mask layer 18, which has openings 18a in regions above electrodes 11 of the semiconductor substrate 1, is provided on the upper surface (the lower surface in FIG. 2A) of the semiconductor substrate 1. Next, the semiconductor substrate 1 and the insulating film 13 are removed from the openings 18a using a technique such as dry etching so that through holes 7 to reach a surface of the electrode 11 are formed. In this step, residues of the mask layer 18 are removed by, for example, plasma ashing or a wet process before or after the insulating film 13 is penetrated. As necessary, the through holes 7 may be formed by wet etching as well as dry etching, for which a preferable etching gas and an etching solution are selected, respectively.

Next, as shown in FIG. 5C, an insulating film 8 is formed on the inside walls of the through holes 7 and the upper surface (the lower surface in FIG. 2A) of the semiconductor substrate 1 in a manner such that at least part of the surface of each of the electrodes 11 is exposed. Here, the insulating film 8 is formed by, for example, first integrally forming a chemical vapor deposition (CVD) film of silicon oxide to cover all over the inside walls of the through holes 7 and the upper surface of the semiconductor substrate 1, and then removing the insulating film 8 from the bottoms of the through holes 7 to expose the surfaces of the electrodes 11.

Next, a conductive body having a desired shape is formed in the through holes 7 and on the upper surface side of the semiconductor substrate 1, and then through electrodes 6 and wiring are provided from the electrodes 11 to the external electrodes 12. FIG. 5D to FIG. 5F show an example thereof.

First, as shown in FIG. 5D, a conductive film 9, which includes one or more layers, is formed by, for example, spattering so as to cover the inside walls of the through holes 7, the insulating film 8 formed on the upper surface (the lower surface in FIG. 2A) of the semiconductor substrate 1, and the exposed surfaces of the electrodes 11 at the bottoms of the through holes 7.

Next, as shown in FIG. 5E, a mask layer 19 is formed on the conductive film 9 in a manner such that the mask layer 19 has openings in regions where through electrodes 6 are to be formed and where wiring having a desired shape are to be formed. Then, conductive bodies 10 are formed by plating. Here, for example, it is preferable that the conductive film 9 be stacked films of Ti/Cu and that the conductive bodies 10 include Cu. It is also preferable that the mask layer 19 cover at least the scribe region and that the conductive bodies 10 be not formed in the scribe region so that the semiconductor substrate 1 can be easily diced in a step described later.

Next, as shown in FIG. 5F, the mask layer 19 is removed by a wet process, and then the conducting film 9 is removed using a technique such as wet-etching using the conductive bodies 10 as masks so that the conductive film 9 are removed from the regions other than the regions where the conductive bodies 10 are present. Electrical paths from the electrode 11 to the conductive film 9 and the conductive bodies 10 are thus formed.

Although the insulating film 8 in the method according to the embodiment covers all over the upper surface of the semiconductor substrate 1, the insulating film 8 needs to be formed at least between the conductive bodies 10 and the semiconductor substrate 1. Therefore, when the conductive film 9 is removed in the step shown in FIG. 5F, the insulating film 8 may be removed together from the part where the conductive bodies 10 are not present by the etching. Alternatively, the through electrodes 6 and wiring may be formed in the same step by etching the conductive bodies 10, which have been formed all over the conductive film 9 and masked in the part where the through electrodes 6 are to be formed and the part where wiring having a desired shape is to be formed.

Next, as shown in FIG. 5G, an overcoat 15 is formed on the upper surface side of the semiconductor substrate 1 (the lower surface side of FIG. 2A) in order to provide electrical insulation and surface protection on the upper surface side of the semiconductor substrate 1. The overcoat 15 is formed to cover the conductive bodies 10 at least in the parts which serve as the external terminals 10a. It is preferable that the overcoat 15 secure electrical insulation and have an opening at least above the scribe region so that the semiconductor substrate 1 can be easily diced

Next, as shown in FIG. 5H, external electrodes 12 are connected to the external terminals 10a on the conductive bodies 10. For example, the external electrodes 12 are formed by placing solder balls on the external terminals 10a and bonding the solder balls to the external terminals 10a by processing such as reflow processing. In consideration of adaptivity to the dicing process, the external electrodes 12 may be formed after the dicing process, which is described later.

The following describes steps through which an intermediate product is diced into singulated unit structures each having the light-receiving element 2 with reference to the FIG. 6A to FIG. 6C on the basis of the features of the present invention. The intermediate product is the large semiconductor substrate 1 on which unit structures are formed with regular intervals. It is to be noted that, in steps shown in FIG. 6A to FIG. 6C, the fabrication process is advanced with the semiconductor substrate 1 disposed upside down from that shown in FIG. 5H. The vertical directions in FIG. 6A to FIG. 6C are the same as those indicated in FIG. 1, FIG. 2A, and FIG. 2B, and described according to FIG. 6A to FIG. 6C.

First, as shown in FIG. 6A, the semiconductor substrate 1 is inverted, and the adhesive layer 20a and the surface of the overcoat 15 are bonded to each other in a manner such that the external electrodes 12 are buried in the adhesive layer 20a of a dicing sheet 20. In this position, a dicing blade 21 is applied to the light-transmissive substrate 4 in a scribe region A from the upper surface of the light-transmissive substrate 4, and the dicing blade 21 is moved along a separation line (scribe line) so that a linear blind groove is formed.

Here, when the blind groove is formed in the step shown in FIG. 6A using a dicing blade 21 having a blade provided with a desired widthwise shape, the shape of the blade is replicated to the curved surface 4A along the separation line in the light-transmissive substrate 4A so that the curved surface 4A is formed to have a desired shape. Use of a blade having a curved surface such that the blade tapers toward its edge as the dicing blade 21 reduces cutting resistance and allows sawdust to be eliminated better so that the intermediate product is damaged less during dicing and provided with the desired curved surface 4A. The light-transmissive substrate 4 has such a curved surface 4A formed using the tapered blade that the farther away from the separation line, the thicker the light-transmissive substrate 4 is. With this, occurrence of damage to elements near the separation line during dicing is reduced. In addition, forming the curved surface 4A using the dicing blade 21 provides the curved surface 4A with such roughness that the light reflected from and transmitted through the curved surface 4A is reduced, and thus an effect of reducing optical noise can be expected.

In addition, a shallow groove may be formed also in the semiconductor substrate 1 in the scribe region A by providing the integrated semiconductor substrate 1 and light-transmissive substrate 4 with a blind groove penetrating through the light-transmissive substrate 4 in the step shown in FIG. 6A so that the blind groove reaches the inside of the semiconductor substrate 1. The groove forms the shape of the curved surface 1A chamfered in the peripheral region of the singulated semiconductor substrate 1, so that occurrence of chipping in processes of dicing and handling subsequent to the dicing is reduced.

Next, as shown in FIG. 6B, a defect 1B is formed within the semiconductor substrate 1 in the scribe region A by, for example, irradiating the exposed part of the upper surface of the semiconductor substrate 1 with laser using a laser generating apparatus 22. The defect 1B serves as an origin of separation. Subsequently the semiconductor substrate 1 is separated into singulated chips at the defect 1B serving as the origin by, for example, pulling (expanding) the dicing sheet 20 outward. The integrated semiconductor substrate 1 and light-transmissive substrate 4 are thus divided so that a curved surface is formed in the peripheral end face of the light-transmissive substrate 4 and the curved surface slopes so as to flare from the upper surface toward the lower surface. The semiconductor substrate 1 and light-transmissive substrate 4 may be not divided by the expanding but cleaved by pressing both ends of the semiconductor substrate 1 using the upper surface of the semiconductor substrate 1 in the scribe region A as a fulcrum. Alternatively, the semiconductor substrate 1 may be diced by cutting the semiconductor substrate 1 along the separation line using a dicing blade having a thickness smaller than the width of the blind groove formed as shown in FIG. 6A to remove a region having a width smaller than the width of the blind groove at the bottom of the blind groove. Cutting the semiconductor substrate 1 using such a dicing blade having a thickness smaller than the width of the groove in the upper surface of the semiconductor substrate 1 only cuts semiconductor substrate 1, so that occurrence of damage during dicing is reduced.

As described above, the solid-state imaging devices, which are singulated unit structures as shown in FIG. 6C, are provided through the processes shown in FIG. 5A to FIG. 6B.

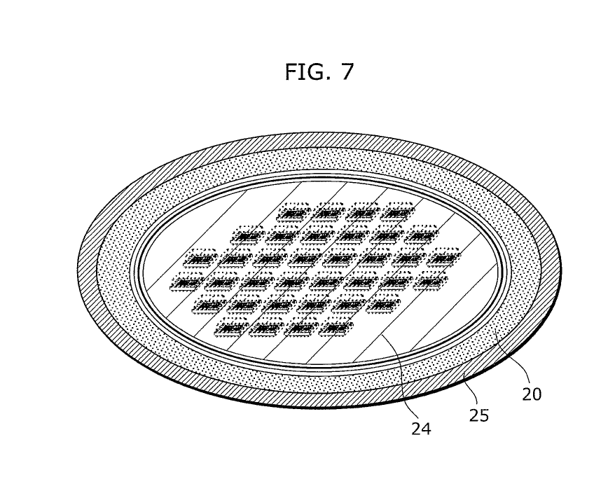

For example, the solid-state imaging device thus fabricated is mounted on the circuit board 16 and integrated into the optical module including the lens tube 17A as shown in FIG. 4, and are to be included in various types of optical apparatuses. The process of dicing and the process of installing the lens tube 17A are usually performed in different manufacturing lines. It is therefore preferable that the solid-state imaging device be sealed by covering the upper surface of the light-transmissive substrate 4 with a protective sheet or the like to prevent dust from attaching to the upper surface during transportation of the solid-state imaging devices. Here, when a protective seal is provided on the upper surface of the light-transmissive substrate 4 of the singulated solid-state imaging device, dust attaches around the protective seal. It is therefore preferable that the solid-state imaging device be sealed by bonding a large protective sheet 24 to the peripheral region of the dicing sheet 20 which has the singulated solid-state imaging devices thereon and is expanded using an expanding ring 25 as shown in FIG. 7. With this, the solid-state imaging devices are transported in a condition free from dust.

As described above, the method of manufacturing the solid-state imaging device according to the embodiment allows forming of the curved surface 4A at the peripheral region of the light-transmissive substrate 4 in the process of dicing the semiconductor substrate 1.

When the light-transmissive substrate 4 and the semiconductor substrate 1 attached to each other are cut together, there may be an increase in damage during dicing because the materials to be cut are different. However, the method of manufacturing the solid-state imaging device according to the embodiment reduces damage during dicing by separating the solid-state imaging device in two steps (the step of separating the light-transmissive substrate 4 and the step of separating the semiconductor substrate 1). In addition, as described above, penetrating through the light-transmissive substrate 4 in the first step of the separating to form a groove which reaches to the inside of the semiconductor substrate 1 and chamfering the upper surface of the semiconductor substrate 1 reduces occurrence of chipping in the second step of the separating and handling after the process of dicing. Furthermore, the amount of cutting in the semiconductor substrate 1 in the first step of the separating is reduced and use of a blade tapered toward the edge increases machinability as described above so that burden on the dicing blade is reduced and wearing of the blade slows. The blade is therefore used for a longer period. The reduction in burden during blade-dicing increases the speed of dicing and the number of solid-state imaging devices obtained from a semiconductor substrate due to a narrower scribe region A, and thus productivity of the solid-state imaging device is increased.

(Variations)

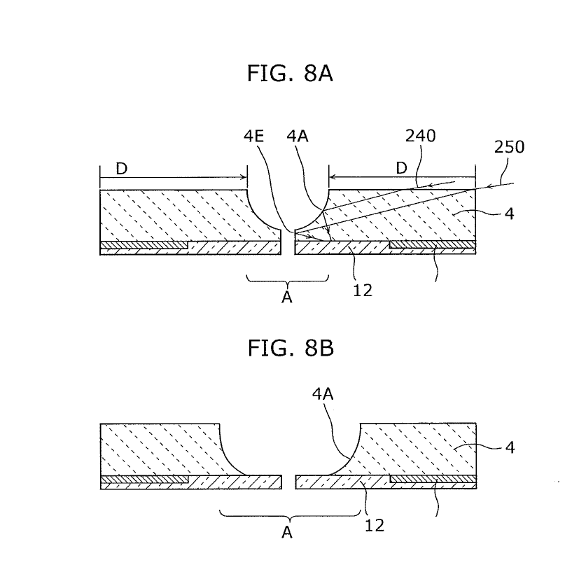

The following describes variations of the method of manufacturing the solid-state imaging device according to the embodiment with reference to FIG. 8A and FIG. 8B. FIG. 8A and FIG. 8B illustrate sectional views of two solid-state imaging devices sandwiching a scribe region A. For simplicity of illustration, FIG. 8A and FIG. 8B schematically show only the light-transmissive substrate 4, the semiconductor substrate 1, and the light-receiving element 2, and other components are omitted.

In the case of a solid-state imaging device shown in FIG. 8A, the upper surface side of the peripheral end face of the light-transmissive substrate 4 is formed to be the curved surface 4A, and the lower surface side of the peripheral end face (a part of the peripheral end face of the light-transmissive substrate 4 in contact with the lower surface of the light-transmissive substrate 4) is formed to be a perpendicular face 4E which is perpendicular to the lower surface of the light-transmissive substrate 4 and the upper surface of the semiconductor substrate 1.

In this configuration, the slope of the curved surface 4A with respect to the upper surface region D of the light-transmissive substrate 4, which is parallel to the light-receiving element 2, may be made relatively moderate. The curved surface 4A therefore prevents reflection of oblique incident light 240, which has a relatively large incident angle and is reflected off the peripheral end face of the light-transmissive substrate 4 from entering the light-receiving element 2. In this case, oblique incident light 250 incident on the perpendicular face 4E of the light-transmissive substrate does not cause a problem because the perpendicular face 4E is so close to the lower surface of the light-transmissive substrate 4 that the reflection of the oblique incident light 250 reflected off the perpendicular face 4E travels too short a distance to reach the light-receiving element 2. Such a configuration may be provided by, in the steps shown in FIG. 6A and FIG. 6B, forming a blind groove in the light-transmissive substrate 4 in the scribe region A in a manner such that the blind groove does not reach the lower surface of the light-transmissive substrate 4, and then blade-dicing the remaining part of the light-transmissive substrate 4 and the semiconductor substrate 1 at a time using a blade having a thickness smaller than the width of the blind groove to remove a region having a width smaller than the width of the blind groove and at the bottom of the blind groove. Here, damage during dicing is reduced because the amount of cutting the light-transmissive substrate 4 in depth is smaller by the decrease in the depth of the blind groove. The present configuration is appropriate for a case, for example, where the solid-state imaging device is a back-side illumination optical device including an ultra-thin semiconductor substrate 1.

In the case of a solid-state imaging device shown in FIG. 8B, the curved surface 4A at the peripheral end face of the light-transmissive substrate 4 is formed not by blade-dicing but by other techniques such as etching. For example, in the case where the curved surface 4A is formed by etching, a blind groove is formed in the step shown in FIG. 6A, by etching in a manner such that the blind groove reaches the lower surface of the light-transmissive substrate 4, and then only the semiconductor substrate 1 is cut at a width smaller than the width of the bottom part of the blind groove in the step shown in FIG. 6B. In the present configuration, damage due to separating is reduced. Alternatively, the curved surface 4A may be made rough using a technique such as sandblasting to form a blind groove in the light-transmissive substrate which is a glass substrate.

Although the optical device according to the present invention has been described according to the embodiment, the present invention is not limited to the embodiment. The present invention also includes variations of the embodiment conceived by those skilled in the art unless they depart from the spirit and scope of the present invention.

For example, the through electrodes 6 are not essential for the optical device according to the present invention. In the optical device according to the present invention, the light-transmissive substrate 4 needs to have a peripheral end face at least part of which is a curved surface sloping so as to flare from the upper surface toward the lower surface. The optical device may be configured in various manners as long as the optical device falls within the spirit and scope of the present invention. For example, when the light-receiving element 2 is formed to be closer to the upper surface of the semiconductor substrate 1, the curved surface may be formed not on the side of the light-transmissive substrate 4 where the peripheral region is sufficiently wide but only on the side of the light-transmissive substrate 4 where the peripheral end face peripheral region is narrower.

In addition, the optical device according to the present invention is applicable to various types of semiconductor devices such as a back-side illumination optical device, a light-receiving device, and a light-emitting device, and electronic apparatuses including any one of such semiconductor devices. In this case, main components of the optical device according to the present invention is not limited to the configuration shown in the embodiment but may be adapted to an optical element included in the optical device. In the solid-state imaging device according to the above embodiment, the light-receiving element 2 is formed in the upper surface of the semiconductor substrate 1, and the external terminal 10a is formed in the lower surface of the semiconductor substrate 1, and the light-receiving element 2 and the external terminal 10a are electrically connected to each other with the through electrode 6. In contrast, in a back-side illumination optical device, no through electrode is provided, and both of the light-receiving element 2 and the external terminal 10a are formed in the lower surface of the semiconductor substrate 1, and electrically connected to each other with no through electrode. In addition, in the solid-state imaging device according to the above embodiment, the adhesive layer 5 is formed so as to cover the surface of the light-receiving element 2. However, for example, in a light-receiving device, the adhesive layer may be provided with an opening in a region where a light-receiving element is present so that the adhesive layer 5 is formed only in the peripheral region of the semiconductor substrate 1 in order to prevent photo-deterioration of the adhesive layer. Alternatively, considering the resistance of the adhesive layer 5 to dampness, the light-transmissive substrate 4 may be formed directly on the upper surface of the semiconductor substrate 1.

In the case where the optical device according to the present invention is a back-side illumination optical device and the semiconductor substrate 1 is ultra-thin, the dicing process may not be performed in two steps and the light-transmissive substrate 4 and the semiconductor substrate 1 may be blade-diced at a time. Also in this case, use of a blade tapered toward the edge reduces damage during dicing and provides a desired curved surface 4A.

In the above method of manufacturing the solid-state imaging device, an intermediate body prepared by bonding the large semiconductor substrate 1 and the large light-transmissive substrate 4 is diced into singulated solid-state imaging devices. However, the solid-state imaging device may be manufactured by bonding the semiconductor substrate 1 and the light-transmissive substrate 4 after at least one of which is diced.

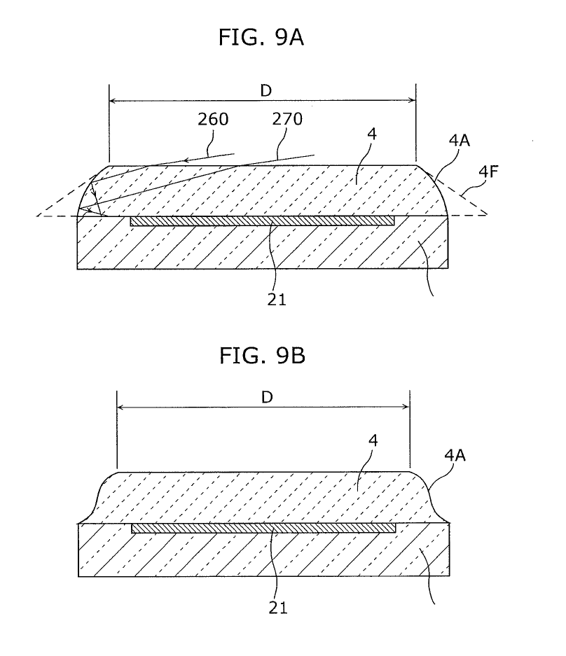

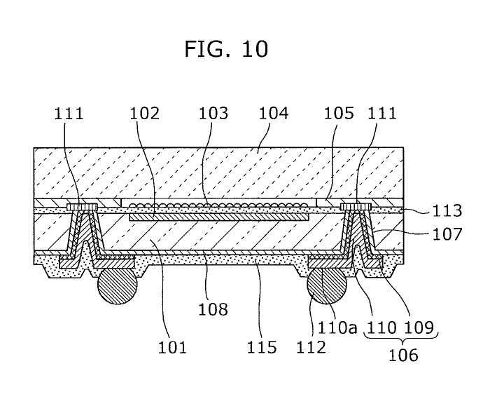

In the solid-state imaging device according to the embodiment, the peripheral end face of the light-transmissive substrate 4 is a recessed curved surface (arc-shaped concave curve) 4A in the peripheral end face, that is, a curved surface which becomes gradually steeper from the lower surface toward the upper surface of the light-transmissive substrate 4. However, the shape of the curved surface is not limited to this. A curved surface having a different shape also produces an effect of reducing occurrence of noise due to reflection of such oblique incident light reflected off the peripheral end face of the light-transmissive substrate 4. The following are examples of such shapes according to the embodiment with reference to FIG. 9A and FIG. 9B. FIG. 9A and FIG. 9B schematically illustrate cross-section structures of the solid-state imaging device according to the embodiment. For simplicity of illustration, FIG. 9A and FIG. 9B schematically show only the light-transmissive substrate 4, the semiconductor substrate 1, and the light-receiving element 2, and other components are omitted.

In the solid-state imaging device shown in FIG. 9A, the light-transmissive substrate 4 has a curved surface 4A in which the peripheral end face protrudes (arc-shaped convex curve), that is, a curved surface 4A which becomes gradually less steep from the lower surface toward the upper surface of the light-transmissive substrate 4. This configuration provides an advantage in miniaturization of the light-transmissive substrate 4 because an upper surface region D of the light-transmissive substrate 4, which is parallel to the light-receiving element 2, keeps the size while the size of the light-transmissive substrate 4 is small in comparison with the case where a slope 4F is formed at the peripheral end face of the light-transmissive substrate 4. In addition, the oblique incident light 260 reflected off the curved surface 4A in the upper-surface side part thereof, where the curved surface is less steep, is directed downward, so that the reflection is prevented from entering the light-receiving element 2. Similarly, the oblique incident light 270 reflected off the curved surface 4A in the lower-surface side part thereof, where the curved surface is steeper, travels too short a distance to reach the light-receiving element 2. Noise due to reflection off the peripheral end face of the light-transmissive substrate 4 is thus prevented.

In the solid-state imaging device shown in FIG. 9B, the light-transmissive substrate 4 has a curved surface 4A in which a peripheral end face has an inflection point. Also in this configuration, noise due to reflection from the peripheral end face of the light-transmissive substrate 4 is prevented.

The curved surface 4A in the peripheral end face of the light-transmissive substrate 4 in the solid-state imaging device shown in FIG. 9A and FIG. 9B has such a round shape provided by, for example, etching only the upper end of the peripheral end face of the light-transmissive substrate 4 or ion-milling the upper corner to chamfer and round off it. In this manner, such a rounded curved surface 4A in the peripheral end face of the light-transmissive substrate 4 prevents generation of dust which is generated from wiping rags hooked by the peripheral end face of the light-transmissive substrate 4 in a process of wiping the upper surface of the light-transmissive substrate 4 before mounting the light-transmissive substrate 4 in the lens tube 17A.

It should be understood that, in the above description, one of the main surfaces of the semiconductor substrate is referred to as an upper surface and the other as a lower surface for reasons of explanation, a semiconductor substrate has the same advantageous effects even when the upper surface and the lower surface are switched.

### INDUSTRIAL APPLICABILITY

The present invention is applicable to optical devices and a method of manufacturing them and particularly to digital optical devices such as digital still cameras, cameras for mobile phones, and camcorders, and various optical sensors of devices such as medical devices.

What is claimed is:

1. An optical device comprising:
a semiconductor substrate in which an optical element is formed; and
a light-transmissive substrate provided above said semiconductor substrate so as to cover said optical element,
wherein said light-transmissive substrate has, in a peripheral end face, a curved surface which slopes so as to flare from an upper surface of said light-transmissive substrate toward a lower surface of said light-transmissive substrate.

2. The optical device according to claim 1,
wherein said semiconductor substrate has, in a peripheral end face, a curved surface which forms a continuous curve with the curved surface of said light-transmissive substrate.

3. The optical device according to claim 1,
wherein said light-transmissive substrate has, in a part of the peripheral end face, a surface perpendicular to the lower surface of said light-transmissive substrate, the part being in contact with the lower surface of said light-transmissive substrate.

4. The optical device according to claim 1,
wherein the curved surface in the peripheral end face of said light-transmissive substrate is a round surface.

5. The optical device according to claim 1,
wherein the curved surface is a rough surface.

6. The optical device according to claim 1, further comprising
a light shield film provided on the upper surface of a peripheral region of said light-transmissive substrate and on the curved surface.

7. The optical device according to claim 1, further comprising
a lens tube disposed with reference to an upper surface of a peripheral region of the said light-transmissive substrate,
wherein said lens tube structurally shields the upper surface of the peripheral region and the curved surface of said light-transmissive substrate from light.

8. The optical device according to claim 1,
wherein the lower surface of said light-transmissive substrate is equivalent in area to an upper surface of said semiconductor substrate.

9. The optical device according to claim 1,
wherein said optical element is formed in an upper surface of said semiconductor substrate, and
said optical device further comprises:
an external terminal provided below a lower surface of said semiconductor substrate; and
a through electrode provided through said semiconductor substrate and electrically connecting said optical element and said external terminal.

10. The optical device according to claim 1,
wherein said optical element is formed in a lower surface of said semiconductor substrate, and
said optical device further comprises an external terminal provided below the lower surface of said semiconductor substrate and electrically connected to said optical element.

11. The optical device according to claim 1,
wherein the curved surface is a recessed curved surface.

12. The optical device according to claim 1,
wherein the curved surface is a protruding curved surface.

13. An optical apparatus in which the optical device according to claim 1 is installed.

14. A method of manufacturing an optical device, said method comprising:
providing a light-transmissive substrate above a semiconductor substrate having a plurality of optical elements so as to integrate the semiconductor substrate and the light-transmissive substrate in a manner such that the optical elements are covered with the light-transmissive substrate;
dicing the integrated semiconductor substrate and light-transmissive substrate,
wherein, in said dicing, the integrated semiconductor substrate and light-transmissive substrate are divided in a manner such that a curved surface is formed in a peripheral end face of the light-transmissive substrate, the curved surface sloping so as to flare from an upper surface of the light-transmissive substrate toward a lower surface of the light-transmissive substrate.

15. The method of manufacturing an optical device according to claim 14,
wherein said dicing includes:
forming, in the integrated semiconductor substrate and light-transmissive substrate, a groove which penetrates through the light-transmissive substrate to reach an inside of the semiconductor substrate; and
removing a region located at a bottom of the groove and having a width smaller than a width of the groove.

16. The method of manufacturing an optical device according to claim 14,
wherein said dicing includes:
forming a blind groove in the light-transmissive substrate; and
removing an area located at a bottom of the groove and having a width smaller than a width of the groove.

17. The method of manufacturing an optical device according to claim 14,
wherein, in said dicing, said dividing is performed using a dicing blade tapered toward an edge.
